(19) United States
(12) Patent Application Publication
(10) Pub. No.: US 2026/0124904 A1
(43) Pub. Date: May 7, 2026

(54) THERMAL MANAGEMENT FOR HYBRID MINING TRUCKS

(71) Applicant: Cummins Inc., Columbus, IN (US)

(72) Inventors: Kieran J. Richards, Northamptonshire (GB); Tanner Trudell, Columbus, IN (US); Daniel C. Sopp, Northampton (GB)

(21) Appl. No.: 18/935,002

(22) Filed: Nov. 1, 2024

(51) Int. Cl. B60K 11/04; H05K 7/20

(52) U.S. Cl. CPC B60K 11/04; H05K 7/20263

(57) ABSTRACT

A mining truck can include a resistor grid, an electronics unit, and a thermal management system positioned on a deck of the mining truck. The thermal management system can include an air transfer zone arranged between the resistor grid and the electronics unit. The air transfer zone can be configured to receive exhaust air from the resistor grid. The thermal management system can further include one or more heat exchangers positioned above the resistor grid. The one or more heat exchangers can be configured to receive a cooling fluid for cooling one or more electronic components of the mining truck.

### TECHNICAL FIELD OF THE PRESENT DISCLOSURE

The present disclosure relates to architectures, or component arrangements, of hybrid mining trucks. In particular, the present disclosure relates to the arrangement of vehicle components associated with a thermal management system of a hybrid mining truck.

### BACKGROUND OF THE PRESENT DISCLOSURE

Environmental and efficiency considerations have resulted in the electrification of vehicles across industries and purposes. While electric and hybrid passenger and cargo vehicles are becoming more commonplace, electrification and/or hybridization of large equipment vehicles poses its own set of challenges. For example, large equipment vehicles, such as mining trucks, cranes, bulldozers, etc., may require a workload and/or have a sheer size component that make implementation of alternative powertrains more difficult. Additionally, the components required for hybridization and/or electrification of such vehicles may be difficult to arrange due to the space available relative to the respective vehicle for mounting such components.

### SUMMARY OF THE DISCLOSURE

A mining truck can include a resistor grid, an electronics unit, and a thermal management system. The resistor grid, electronics unit, and thermal management system can be positioned on a deck of the mining truck. The thermal management system can include an air transfer zone. The air transfer zone can be arranged between the resistor grid and the electronics unit. The air transfer zone can be configured to receive exhaust air from the resistor grid. The thermal management system can further include one or more heat exchangers. The one or more heat exchangers can be positioned above the resistor grid. The one or more heat exchangers can be configured to receive a cooling fluid. The cooling fluid can be for cooling one or more electronic components of the mining truck.

In a first aspect of the disclosure, a mining truck is provided. The mining truck includes a chassis extending along a longitudinal length of the mining truck. The chassis has a front end portion and a rear end portion. The mining truck further includes a deck supported by the front end portion of the chassis, a resistor grid supported by the deck, an electronics unit supported by the deck and spaced apart from the resistor grid, and an air transfer zone arranged between the resistor grid and the electronics unit. The air transfer zone is configured to receive exhaust air from the resistor grid.

In another aspect of the disclosure, a mining truck is provided. The mining truck includes a chassis extending along a longitudinal length of the mining truck, a deck supported by the chassis, a resistor grid supported by the deck, and one or more heat exchangers positioned above the resistor grid. The one or more heat exchangers are configured to receive a cooling fluid for cooling one or more electronic components of the mining truck.

In various aspects of the disclosure, the electronics unit may include a battery.

In various aspects of the disclosure, the mining truck may further include an insulation layer disposed between the air transfer zone and the electronics unit.

In various aspects of the disclosure, the resistor grid is configured to move the exhaust air in a first direction. The air transfer zone may form a flow path in a second direction that is substantially perpendicular to the first direction. The resistor grid may include one or more fins oriented to direct the exhaust air toward the second direction. The air transfer zone may be configured to vent the exhaust air in the second direction. The deck may have a first side and a second side opposite the first side. The second side may include an operator cab of the mining truck. The first side may include the air transfer zone. The air transfer zone may be configured to vent the exhaust air away from the mining truck from the first side. The second direction may extend from the first side to an ambient area adjacent the first side. The mining truck may further include a mirror coupled to the first side of the mining truck and a line-of-sight defined between the mirror and the operator cab. Neither of the resistor grid nor the electronics unit may intersect the line-of-sight defined between the mirror and the operator cab.

In various aspects of the disclosure, the electronics unit may include one or more DC/DC converters.

In various aspects of the disclosure, the resistor grid may include a top-side access panel.

In various aspects of the disclosure, the mining truck further includes one or more condenser tubes positioned above the resistor grid.

In various aspects of the disclosure, the mining truck may further include a front support member positioned between the resistor grid and the air transfer zone. The front support member may include an upper portion and a lower portion. The upper portion may be removably attached to the lower portion.

In various aspects of the disclosure, the mining truck may further include an electronics unit spaced apart from the resistor grid and an air transfer zone arranged between the resistor grid and the electronics unit. The one or more heat exchangers may be positioned above the air transfer zone, such that the air transfer zone is enclosed by the resistor grid, the electronics unit, the deck, and a base support member of the one or more heat exchangers. The mining truck may further include an insulation layer disposed between the air transfer zone and the one or more heat exchangers. The one or more heat exchangers may be positioned above the electronics unit.

In various aspects of the disclosure, the one or more electronic components of the mining truck may include a battery of the mining truck and an electronics unit positioned on the deck. The one or more heat exchangers may include a first heat exchanger configured to cool the battery of the mining truck and a second heat exchanger configured to cool the electronics unit. The mining truck may further include a radiator configured to cool the electronics unit. The one or more heat exchangers may be configured to cool the battery of the mining truck.

While multiple embodiments are disclosed, still other embodiments of the present disclosure will become apparent to those skilled in the art from the following detailed description, which shows and describes illustrative embodiments of the disclosure. Accordingly, the drawings and detailed description are to be regarded as illustrative in nature and not restrictive.

### BRIEF DESCRIPTION OF THE DRAWINGS

The detailed description of the drawings particularly refers to the accompanying figures in which:

FIG. 1 is a schematic top-down illustration of an architecture arrangement of components of a mining truck;

FIG. 2 illustrates a top-down schematic illustration of another architecture arrangement of components of a mining truck;

FIG. 3 illustrates a top-down schematic illustration of an arrangement of zones on a deck of a mining truck;

FIG. 4A illustrates a side view of a thermal management system of a mining truck, in accordance with embodiments of the present disclosure;

FIG. 4B illustrates a plan view of the thermal management system of FIG. 4A, in accordance with embodiments of the present disclosure;

FIG. 5A illustrates a side view of a thermal management system of a mining truck, in accordance with embodiments of the present disclosure;

FIG. 5B illustrates a plan view of the thermal management system of FIG. 5A, in accordance with embodiments of the present disclosure;

FIG. 6 illustrates a side view schematic illustration of an architecture arrangement of a mining truck including an on-board trolley system; and

FIG. 7 is an illustration of a mining truck including an on-board trolley system.

Although the drawings represent embodiments of various features and components according to the present disclosure, the exemplification set out herein illustrates an embodiment, and such an exemplification is not to be construed as limiting the scope of the disclosure in any manner.

### DETAILED DESCRIPTION OF THE DRAWINGS

The present disclosure relates to architectures, or component arrangements, of hybrid mining trucks; more particular aspects relate to architectures associated with a thermal management system of a hybrid mining truck.

As noted above, in view of environmental and efficiency considerations, there are efforts to electrify and/or hybridize large equipment vehicles (e.g., mining trucks, cranes, bulldozers). The size and workload of such vehicles can present a variety of challenges to alternative powertrain configurations. In some instances, the work environment of such vehicles can include elevated temperatures, dusty air, and rugged terrain which can present additional challenges to thermal management and operating efficiency of such vehicles. Additionally, some design configurations, such as those including retrofitting an internal-combustion-powered mining truck for hybrid or electric-powered operation, can have a limited available space for installing new components.

To address these and other challenges, embodiments of the present disclosure include an integrated thermal management system. In some embodiments, the thermal management system can, within a compact space, provide efficient and effective heat dissipation for systems of a mining truck. For example, embodiments of the present disclosure include a thermal management system that is structurally integrated with a resistor grid and an electronics unit of a mining truck. This configuration permits simultaneous cooling of the resistor grid and the electronics unit within a compact space on a deck of the mining truck. In some embodiments, the thermal management system can include a heat exchanger (e.g., a heat exchanger core) arranged in a tiered configuration with an air transfer zone. This configuration can facilitate optimal heat transfer by the heat exchanger by permitting a substantially unobstructed flow of air to reach the heat exchanger.

For the purposes of promoting an understanding of the principles of the present disclosure, reference will now be made to the embodiments illustrated in the drawings, which are described herein. The embodiments disclosed herein are not intended to be exhaustive or to limit the invention to the precise form disclosed. Rather, the embodiments are chosen and described so that others skilled in the art may utilize their teachings. Therefore, no limitation of the scope of the claimed invention is thereby intended. The present invention includes any alterations and further modifications of the illustrated devices and described methods and further applications of principles in the invention which would normally occur to one skilled in the art to which the invention relates.

The terms “couples,” “coupled,” “coupler,” and variations thereof are used to include both arrangements wherein the two or more components are in direct physical contact and arrangements wherein the two or more components are not in direct contact with each other (e.g., the components are “coupled” via at least a third component), but yet still cooperate or interact with each other.

In some instances throughout this disclosure and in the claims, numeric terminology, such as first, second, third, fourth, etc., is used in reference to various components of features. Such use is not intended to denote an ordering of the components or features. Rather, numeric terminology is used to assist the reader in identifying the components or features being referenced and should not be narrowly interpreted as providing a specific order of components or features.

While the disclosure herein is provided in terms of a “mining truck”, it is understood that the features described herein may apply to other vehicles, including heavy equipment such as cranes, bulldozers, excavators, etc., locomotives, and other appropriate vehicles.

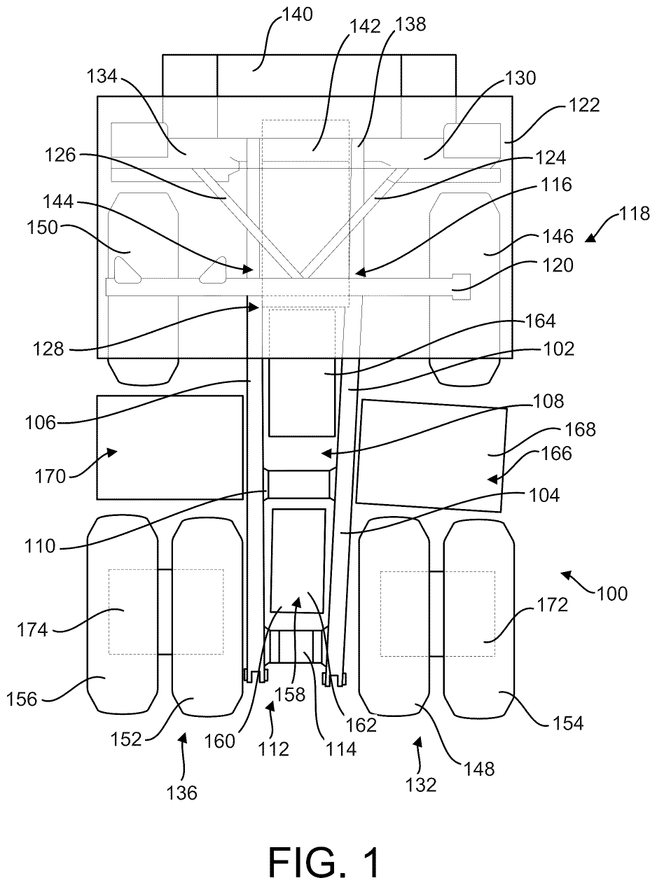

A schematic architecture of an exemplary mining truck 100 is illustrated in FIG. 1. As shown, mining truck 100 may generally be built on and/or around chassis 102. Chassis 102 may include a first frame member 104 and a second frame member 106 extending longitudinally from a first end portion of the chassis, including a first end of the chassis, to a second end portion of the chassis, including a second end of the chassis, to at least partially define a length of mining truck 100. First frame member 104 and second frame member 106 may be spaced apart to form a space 108 therebetween, and a central crossbeam 110 may extend from first frame member 104 to second frame member 106 across space 108, to generally define a rear chassis region 112. A rear crossbeam 114 may extens from first frame member 104 to second frame member 106 across space 108 at the rear of chassis 102, and a horse collar 116 may connect first frame member 104 and second frame member 106 within a forward region 118 of chassis 102.

A third frame member 120 may extend across the top of horse collar 116 and beyond the diameter of horse collar 116 to form a support for a deck 122 (FIG. 1) as described further herein. A first supplemental frame member 124 and a second supplemental frame member 126 may each extend diagonally from a central portion 128 of third frame member 120 above horse collar 116 in opposite directions so that first supplemental frame member 124 may connect to a first support plate 130, and second supplemental frame member 126 may connect to a second support plate 134. First support plate 130 may connect to first frame member 104 on a first side 132 of chassis 102, and second support plate 134 may also connect to second frame member 106 on a second side 136 of chassis 102.

A forward crossbeam 138 may extend from first frame member 104 to second frame member 106 in general alignment with first support plate 130 and second support plate 134. A support extension 140 may extend forward of forward crossbeam 138. An engine 142 may be positioned within an opening 144 defined by horse collar 116. A traction alternator and/or gearbox may be mounted rearward of engine 142 within area 164.

Referring again to FIG. 1, wheels 146, 148, 150, and 152 may be mounted to chassis 102 via respective axles (not shown). For example, as shown, first wheel 146 may be mounted at a forward position in forward region 118 on first side 132 of chassis 102. Second wheel 148 may be mounted at a rearward position in rear chassis region 112 on first side 132 of chassis 102. Third wheel 150 may be mounted at a forward position in forward region 118 on second side 136 of chassis 102. Fourth wheel 152 may be mounted at a rearward position in rear chassis region 112 on second side 136 of chassis 102. In some embodiments, mining truck 100 may include a fifth wheel 154 mounted adjacent to second wheel 148 at a rearward position in rear chassis region 112 on first side 132 of chassis 102. Some embodiments may additionally include a sixth wheel 156 mounted adjacent to fourth wheel 152 at a rearward position in rear chassis region 112 on second side 136 of chassis 102. First wheel 146 and third wheel 150 may be mounted at a position generally corresponding to third frame member 120.

A rear region space 158 defined between first frame member 104 and second frame member 106 within rear chassis region 112, and at least partially defined between second wheel 148 and fourth wheel 152, may be sized and shaped to receive a vehicle subsystem 160. For example, vehicle subsystem 160 may include an aftertreatment system 162. In other embodiments, vehicle subsystem 160 may include a battery module, a fuel tank, a powertrain support subsystem, or any other vehicle subsystems necessary or otherwise desired for operation of mining truck 100. As described herein, an exhaust muffler and an exhaust silencer may be similar or the same components intended to quiet an exhaust by some value, e.g., a decibel value. In other embodiments, rear region space 158 may be free of any vehicle subsystems or components.

First wheel 146 and second wheel 148 may define a space, or first side saddle 166 therebetween. In some embodiments, as illustrated in FIG. 1, a fuel tank 168 may be mounted to chassis 102 within first side saddle 166. Fuel tank 168 may contain, for example, diesel fuel, methanol, ammonia, or another suitable fuel for operation of mining truck 100. Likewise, third wheel 150 and fourth wheel 152 may define a space, or second side saddle 170.

A first wheel motor 172 may be associated with second wheel 148 and, in embodiments including a fifth wheel, fifth wheel 154. A second wheel motor 174 may be associated with fourth wheel 152 and, in embodiments including a sixth wheel, sixth wheel 156. In some embodiments including a fifth and/or sixth wheel, each of second wheel 148, fourth wheel 152, fifth wheel 154, and sixth wheel 156 may have a separate wheel motor. In other embodiments, all of wheels 146, 148, 150, 152, 154, and 156 or wheels 146, 148, 150, 152, or any combination thereof, may be associated with a wheel motor, whether such wheel motor is designated to a single wheel or such wheel motor is shared between two or more wheels.

Still referring to FIG. 1, deck 122 may be supported by chassis 102, and, for example, by third frame member 120, first support plate 130, and second support plate 134. In other words, deck 122 may be supported by the first end portion of chassis 102, wherein the first end portion of chassis 102 includes a first end of chassis 102. Deck 122 is configured to support a cab to facilitate operation of mining truck 100 and various vehicle subsystems, including hybrid powertrain subsystems and components as discussed further herein.

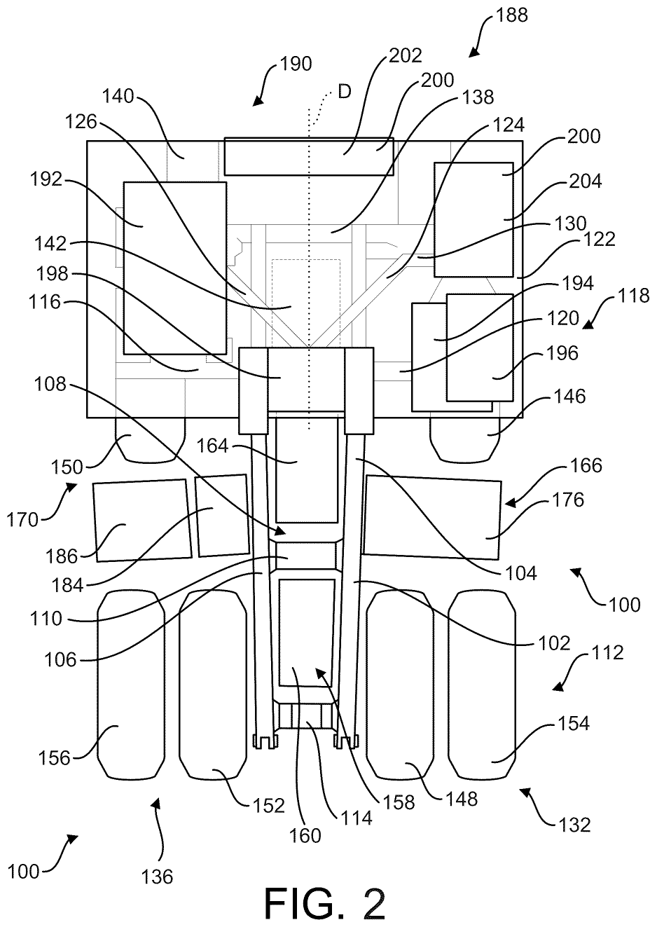

Now referring to FIG. 2, a battery pack module 176 may be mounted to a first side 132 of chassis 102 within first side saddle 166, rather than fuel tank 168 as described above in relation to FIG. 1. Battery pack module 176 is configured to store power for use in operation of mining truck 100. Battery pack module 176 is mounted within first side saddle 166 at a position which mitigates potential contact of any one of wheels 146, 148, 150, 152, 154 (when present) and/or 156 (when present).

Battery pack module 176 may include a plurality of battery pack layers in a vertical arrangement, where each battery pack layer of the plurality of battery pack layers includes one or more battery packs. This vertical arrangement of battery packs as positioned in a side saddle may take advantage of a height of mining truck 100 to include as many battery packs as necessary for efficient operation of mining truck 100 in a hybrid operation mode. Mounting of battery pack module 176 within first side saddle 166 may facilitate an even balance of mining truck 100 when one or more tanks are also mounted to chassis 102 within second side saddle 170 as discussed further herein. This placement may also maximize space for battery positioning while allowing the batteries to be put in a single, unified space rather than distributed in several places over the architecture of mining truck 100. While these benefits are acknowledged, it is also within the scope of this disclosure that battery pack module 176 and/or a plurality of battery packs may be alternately positioned, whether in a single, unified space (i.e., on deck 122, within rear region space 158, or another placement), or in a plurality of places throughout the architecture of mining truck 100.

Still referring to FIG. 2, a hydraulic liquid tank 184 may be mounted to second side 136 of chassis 102 within second side saddle 170. Hydraulic liquid tank 184 may serve as a reservoir for containing excess hydraulic fluid for operation of mining truck 100 and/or serve to hold a supply of hydraulic fluid for operation of mining truck 100. A second liquid tank 186 may be mounted to chassis 102 within second side saddle 170. In some embodiments, second liquid tank 186 may be a fuel tank, such as fuel tank 168 described above.

As illustrated, hydraulic liquid tank 184 may be mounted to chassis 102 at an interior position of second side saddle 170, while second liquid tank 186 can be mounted to chassis 102 at an exterior position of second side saddle 170, so that hydraulic liquid tank 184 is substantially in-between the chassis and the second liquid tank 186. In other embodiments, hydraulic liquid tank 184 and second liquid tank 186 may be alternately arranged. For example, in some embodiments, second liquid tank 186 may be mounted to chassis 102 at an interior position of second side saddle 170, while hydraulic liquid tank 184 may be mounted to chassis 102 at an exterior position of second side saddle 170.

In yet other embodiments, hydraulic liquid tank 184 and second liquid tank 186 may both be arranged at a generally interior position of second side saddle 170 so that one of hydraulic liquid tank 184 and second liquid tank 186 is positioned at a forward position near third wheel 150, and the other of the hydraulic liquid tank 184 and second liquid tank 186 is positioned at a rearward position near fourth wheel 152. In some embodiments, a third liquid tank, for example, a second fuel tank, may be mounted to the chassis 102 within the second side saddle 170. In other embodiments, the second fuel tank may be mounted to chassis 102 within the first side saddle 166 in place of or in tandem with battery pack module 176.

Rear region space 158 defined by chassis 102 between second wheel 148 and fourth wheel 152 may include a vehicle subsystem 160 mounted therein, such as an aftertreatment system, a heating system for a bed of mining truck 100, and/or an exhaust muffler. In some embodiments, rear region space 158 can remain empty of any vehicle subsystems. It is within the scope of the disclosure that other subsystems beyond those listed explicitly herein can be mounted within rear region space 158.

As discussed above, deck 122 is supported at a forward position by chassis 102. Deck 122 includes a first region 188 associated with a first side of deck 122 corresponding with first side 132 of chassis 102 and a second region 190 associated with a second side of deck 122 corresponding with second side 136 of chassis 102. First region 188 and second region 190 are illustrated by dividing line “D”. An operator cab 192 may be arranged within second region 190 of deck 122. Operator cab 192 is configured to house an operator during operation of mining truck 100, along with controls necessary or desired for said operation of mining truck 100.

A resistor grid 194 may be arranged within first region 188 of deck 122 and may be positioned at a generally rearward position of first region 188 of deck 122. An inverter cabinet 198 may be positioned at least partially in first region 188 of deck 122 and at least partially in second region 190 of deck 122. For example, inverter cabinet 198 may be equally positioned in first region 188 and second region 190 or, in some embodiments, be positioned so that a majority of inverter cabinet 198 is in first region 188. In other embodiments, inverter cabinet 198 may be positioned so that a majority of inverter cabinet 198 is in second region 190. As illustrated, inverter cabinet 198 may be positioned at a rear portion of deck 122. The positioning of inverter cabinet 198 in this manner can provide an open area for positioning of additional mining truck components, for example, as described further herein.

Mining truck 100 may further include a thermal management system 200.

Thermal management system 200 may include a radiator 202 and a DC/DC-battery thermal manager 204. In some embodiments, radiator 202 and DC/DC-battery thermal manager 204 may be integrated, i.e., one thermal management component may serve as both radiator 202 and DC/DC-battery thermal manager 204. In other embodiments, radiator 202 may service both engine 142 and DC/DC system 196, while DC/DC-battery thermal manager 204 only services battery pack module 176.

As illustrated, radiator 202 may be mounted to a front of mining truck 100, or, in other words, at a full forward position relative to deck 122. For example, radiator may be, at least in part, mounted to a forward edge of deck 122 so that radiator 202 extends downward from deck 122. In other embodiments, radiator 202 may be mounted to a front of mining truck 100 below deck 122. In yet other embodiments, radiator 202 may be mounted at another position of mining truck 100.

DC/DC-battery thermal manager 204 may be positioned on deck 122 within first region 188 at a forward position of resistor grid 194 and/or DC/DC system 196. DC/DC-battery thermal manager 204 may be configured to be fluidly coupled to battery pack module 176 to provide coolant or refrigerated liquid to battery pack module 176, and/or, in some embodiments, may be fluidly coupled to DC/DC system 196 to provide thermal management services to DC/DC system 196.

DC/DC system 196 may be positioned forward of DC/DC-battery thermal manager 204, so that DC/DC-battery thermal manager 204 is positioned generally between resistor grid 194 and DC/DC system 196. The positioning of the components herein provides access to service panels on top of resistor grid 194, while further accounting for positioning of DC/DC-battery thermal manager 204 in an efficient position relative to DC/DC system 196 and battery pack module 176 mounted within first side saddle 166. The arrangement of components as described in relation to FIG. 2 can also mitigate interference with line-of-sight to side mirrors (not shown) of mining truck 100 from operator cab 192 positioned within second region 190 of deck 122.

The arrangement of components on the deck as described herein are exemplary in nature and can be altered within the scope of the disclosure. For example, in some embodiments, first region 188 and second region 190 can be mirrored or switched. In other embodiments, components can be moved relative to one another and/or relative to deck 122. Positioning of the components of the deck as described herein can mitigate damage and/or poor performance from dust, dirt, mud, and/or other environmental considerations. Furthermore, placement of such components on deck 122 in combination with mounting of battery pack module 176, hydraulic liquid tank 184, and second liquid tank 186 in respective side saddles 166, 170 facilitates weight balance of mining truck 100. However, other placements are within the scope of the disclosure.

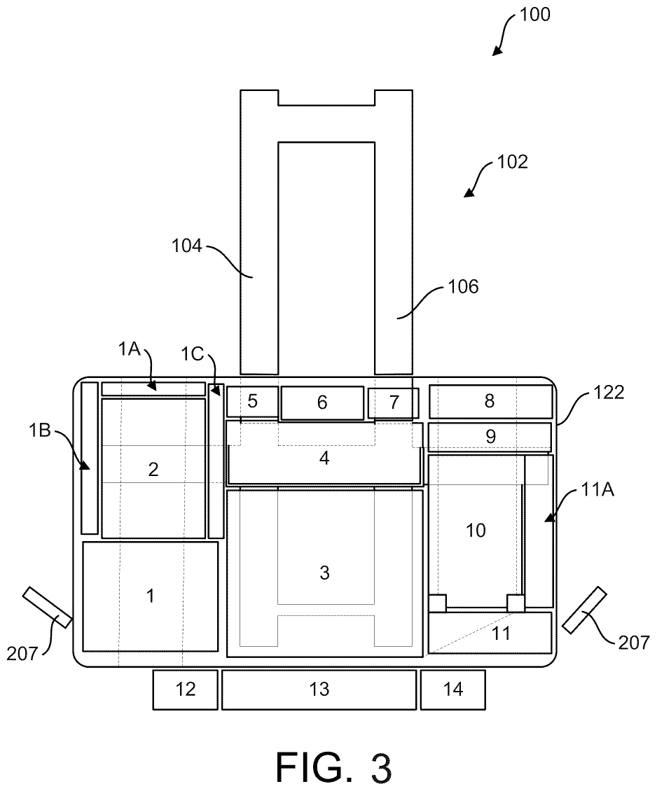

Now referring to FIG. 3, in reference to FIGS. 1-2 above, the positioning of components upon deck 122 of mining truck 100 are further provided in reference to possible requirements of each individual component. In other words, FIG. 3 provides an arrangement of components on deck 122 along with reference to zoned areas for component operation during operation of mining truck 100.

Zone 2 can include a resistor grid, such as resistor grid 194. Zone 2 may be positioned within first region 188 of deck 122 at a generally rearward portion of deck 122 within first region 188. Space around zone 2 may be defined, for example, within zones 1, and 1A to facilitate grid exhaust of resistor grid 194 and zones 1B and 1C to facilitate air intake for resistor grid 194. In other embodiments described above, wherein DC/DC system 196 and/or DC/DC-battery thermal manager 204 is positioned forward of resistor grid 194, a space may be defined between resistor grid 194 and the other of DC/DC system 196 or DC/DC-battery thermal manager 204 to facilitate grid exhaust of resistor grid 194. In other embodiments, such component may be positioned immediately forward of resistor grid 194, with resistor grid exhaust being otherwise concentrated in zone 1A.

Zone 4 may include an inverter cabinet, such as inverter cabinet 198, containing main electrical systems and controls of mining truck 100. Zone 4 may be positioned at least partially in first region 188 of deck 122 and at least partially in second region 190 of deck 122. For example, zone 4 may be equally positioned in first region 188 and second region 190 or, in some embodiments, be positioned so that a majority of zone 4 is in first region 188. In other embodiments, zone 4 may be positioned so that a majority of zone 4 is in second region 190. Zone 4 may be spaced apart from zone 2 for at least zone 1C to facilitate air intake for resistor grid 194.

Zone 4 may be positioned at the rearmost position of deck 122. In some embodiments, as illustrated, zone 6 may be positioned rearward of zone 4 and include blower ducting to provide main traction blower direction from above inverter cabinet 198. Electrical wiring and blowers may further be positioned within zones 5 and 7. Open space zone 3 may be defined in forward of zone 4 to facilitate access to inverter cabinet 198, operator cab 192 in zone 10, and positioning and access to other components such as a trolley pylon as described further herein. For example, zone 3 may include pylon scaffolding for connection to upper pylons in embodiments including trolley pylon systems.

Zone 10 may include operator cab 192 and may be arranged within second region 190 of deck 122. Operator cab 192 is configured to house an operator during operation of mining truck 100, along with controls necessary or desired for said operation of mining truck 100. Zones 11 and 11A around zone 10 may remain open to facilitate operator visibility during operation of mining truck 100. For example, zone 11 may facilitate operator visibility forward of mining truck 100. Zone 11a may facilitate operator visibility of side mirror 207. Zone 11a may further facilitate operator exit from operator cab 192. As discussed above, zone 3 may also provide access to operator cab 192.

Zone 9 may be positioned rearward of operator cab 10 within second region 190 of deck 122 and include a brake and/or hydraulic cabinet. The brake and/or hydraulic cabinet may provide service and maintenance access to brake and/or hydraulic systems of mining truck 100. Zone 8 may be an open space positioned rearward zone 9 to provide access to the brake and/or hydraulic cabinet. In some embodiments, emergency supplies such as fire extinguishers or other supplies may be stored within zone 8.

Radiator 202 may be mounted to mining truck 100 forward of deck 122 in zone 13. In some embodiments, radiator 202 may be mounted to the forward edge of deck 122 or mounted to the front of mining truck 100. A top surface of radiator 202 may include vents and/or service access to radiator 202. Zones 12 and 14 positioned on either side of zone 13 may serve as emergency or primary exit paths, i.e., paths for exiting mining truck 100 and/or deck 122.

The arrangement of components on deck 122 as described herein are exemplary in nature and can be altered within the scope of the disclosure. For example, in some embodiments, first region 188 and second region 190 may be mirrored or switched. In other embodiments, components may be moved relative to one another and/or relative to deck 122.

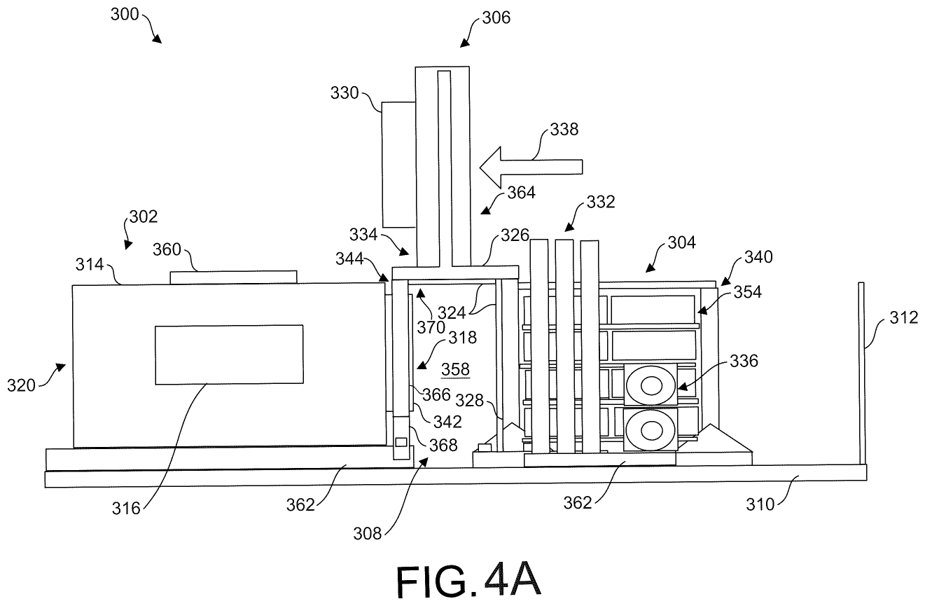

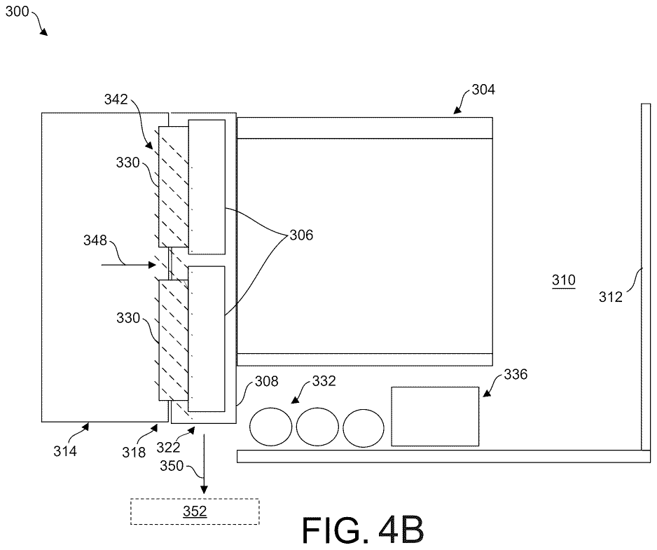

FIGS. 4A and 4B, respectively, show a side view and a plan view of thermal management system 300 on deck 310 of mining truck 100, according to embodiments of the present disclosure. Thermal management system 300 may provide efficient dissipation of heat generated by electronic components (e.g., resistor grid 302, electronics unit 304, and/or battery pack module 176, FIG. 2) of mining truck 100.

Turning to FIG. 4A, thermal management system 300 includes one or more heat exchanger systems 364 and an air transfer zone 308 arranged between resistor grid 302 and electronics unit 304. Thermal management system 300, resistor grid 302, and electronics unit 304 are positioned on deck 310 of mining truck 100. In some embodiments, thermal management system 300, resistor grid 302, and electronics unit 304 may be mounted to one or more skids 362 that are mounted to deck 310.

Deck 310 may include a handrail 312 for personnel safety. Thermal management system 300 may be positioned on deck 310 in a manner that can mitigate interference with a line-of-sight to side mirrors (e.g., side mirrors 207, FIG. 3) of mining truck 100 from operator cab 192. For example, in some embodiments, heat exchangers 306 may be positioned at a distance from handrail 312 that prevents the heat exchangers 306 from obstructing visibility from the operator cab 192 to a side mirror 207 on the first side 132 of the chassis 102 of mining truck 100 (FIG. 2).

In some embodiments, resistor grid 302 may generate heat by receiving electrical energy from the powertrain of mining truck 100 (e.g., regenerative braking energy). Such electrical energy may be transferred to heating elements of resistor grid 302, where it is converted to heat. Resistor grid 302 may include a fan 316 configured to dissipate the heat and cool resistor grid 302. For example, fan 316 may configured to cool resistor grid 302 by drawing in ambient air to be exhausted from a front side 318 and a rear side 320 of resistor grid 302. Heated air exhausted from front side 318 of resistor grid 302 may flow into air transfer zone 308. Front side 318 of resistor grid 302 may include one or more fins (e.g., louvers) 342 oriented at an angle such that fins 342 direct exhaust air from resistor grid 302 toward the air transfer zone outlet 322, FIG. 4B. The exhaust air may then be projected away from mining truck 100 when it exits air transfer zone outlet 322.

In some embodiments of the present disclosure, thermal management system 300 may be configured to cool resistor grid 302 by drawing ambient air into resistor grid 302 from front side 318 and a rear side 320 of resistor grid 302 and exhausting heated air through one or more side panels (e.g., side panel 314) of resistor grid 302. In these embodiments, one or more fans (e.g., fan 316) may be configured to draw in ambient air through rear side 320, air transfer zone 308, and front side 318 and exhaust air heated by resistor grid 302 from side panel 314.

In some embodiments, air transfer zone 308 may be formed by one or more front support members 344; one or more rear support members 328 of electronics unit 304 (e.g., a rear support wall of electronics unit 304); one or more base support members 326 of heat exchangers 306; deck 310; and/or one or more heat shield panels 324. Accordingly, air transfer zone 308 can be enclosed, or surrounded on top, bottom, and lateral sides, by one or more base support members 326 of heat exchangers 306; deck 310; resistor grid 302; and/or electronics unit 304.

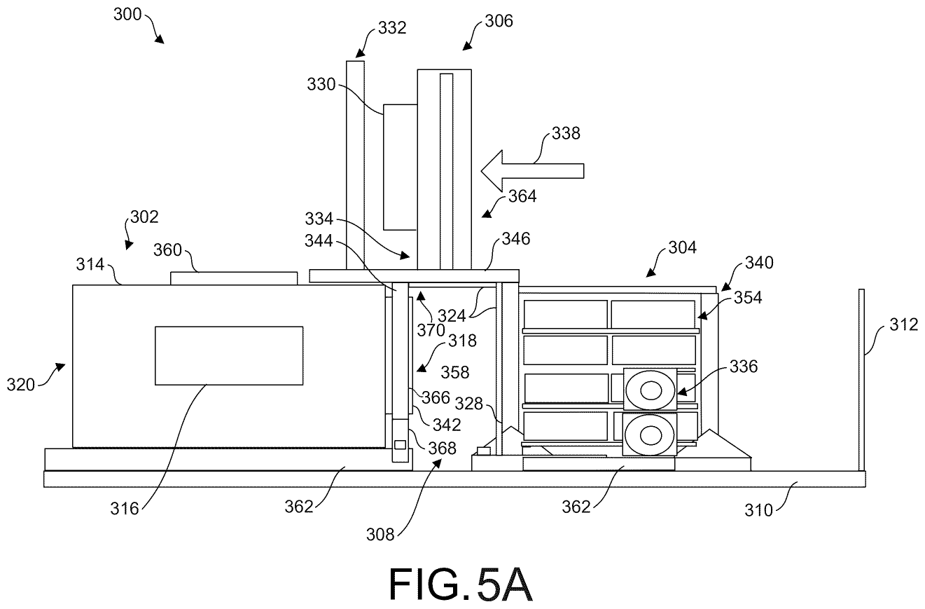

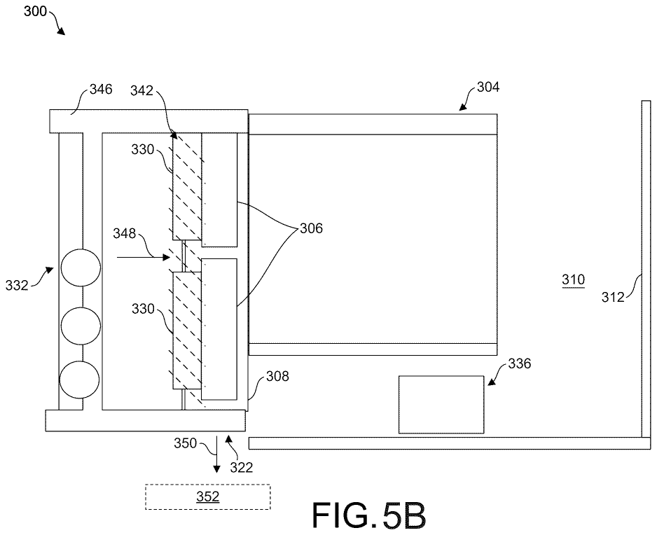

As shown in FIGS. 4A-5B, air transfer zone 308 may be an air transfer tunnel or conduit that directs exhaust air along a central cavity 358 and away from mining truck 100. In these embodiments, base support member 326 supports one or more heat exchangers 306 and mounts to front support members 344 and rear support members 328, such that heat exchangers 306 can be positioned on top of (e.g., directly above) air transfer zone 308.

Base support member 326 (e.g., a metal plate, set of beams, and the like) may form a top wall 370 of air transfer zone 308. In some embodiments, base support member 326 and/or heat exchangers 306 can be positioned on top of resistor grid 302 or on top of electronics unit 304, such that air transfer zone 308 does not include top wall 370. Front support members 344 and rear support members 328 support base support member 326. In some embodiments, front support members 344 and rear support members 328 may include one or more stanchions (e.g., metal posts). In some embodiments, such stanchions may be assembled together (e.g., welded) to form one or more support frames. In some embodiments, front support members 344 may be configured to accommodate resistor grids having various mounting configurations.

In some embodiments, resistor grid 302 may include mounting feet (not shown) that align with front support members 344. In some instances, different-sized resistor grids may have different quantities of mounting feet. To accommodate the different quantities of mounting feet, front support members 344 may include an upper portion 366 and a lower portion 368 that can be removably attached to one another. In this way, lower portion 368 may be interchanged such that a resistor grid having a particular quantity of mounting feet (e.g., two mounting feet) may be mounted with a corresponding lower portion 368 that aligns with the mounting feet.

In some embodiments, heat shield panels 324 may be attached to a surface of base support member 326 and a surface of rear support members 328. Heat shield panels 324 may prevent exhaust air expelled from resistor grid 302 from transferring heat to electronics unit 304 and/or to the cooling fluid of heat exchanger systems 364. Accordingly, heat shield panels 324 may mitigate and/or prevent the cooling of resistor grid 302 from impeding the cooling of electronics unit 304 and/or battery pack module 176 (FIG. 2). Heat shield panels 324 may include materials such as metal (e.g., polished and/or laminated steel or aluminum) and/or fire-resistant/heat insulating material (e.g., fiber, glass fiber, or silicone). In some embodiments, heat shield panels 324 may include a fire-resistant layer attached to a rigid sheet, such as a metal sheet. In some embodiments, heat shield panels 324 may include a plurality of rigid sheets and/or fire-resistant layers.

Electronics unit 304 may include a plurality of components 354 associated with the electrical power of mining truck 100. For example, in some embodiments, the plurality of components 354 may include one or more DC/DC converters, a junction box, a bus bar, and corresponding wiring. Electronics unit 304 may further include an enclosing structure 340 to protect the plurality of components 354. Enclosing structure 340 may include rear support members 328 and a plurality of additional structural components (e.g., metal sheets, additional support members, and the like). In some embodiments, electronics unit 304 may include one or more batteries.

Heat exchanger systems 364 may include one or more of the following: heat exchangers 306; fans 330; condenser tubes 332; and/or flow control devices 336 (e.g., pumps and/or compressors). Heat exchanger systems 364 may further include one or more support frames 334 that support and facilitate mounting of heat exchangers 306. Support frames 334 may further include base support member 326. Flow control devices 336 may move cooling fluid (e.g., water or refrigerant) through heat exchangers 306, condenser tubes 332, and/or a set of pipes (not shown) arranged proximate battery pack module 176 and/or electronics unit 304. This configuration permits heat generated by battery pack module 176 and/or electronics unit 304 to be transferred to the cooling fluid flowing through the set of pipes to the heat exchangers 306.

Heat exchangers 306 may transfer heat from the cooling fluid to the ambient air. In some embodiments, thermal management system 300 may include a first heat exchanger configured to cool a battery of mining truck 100 (e.g., battery pack module 176) and a second heat exchanger configured to cool electronics unit 304. In some embodiments, thermal management system 300 may include one or more heat exchangers 306 configured to cool the battery of mining truck 100, and a radiator of mining truck 100 (e.g., radiator 202, FIG. 2) may be configured to cool electronics unit 304 by supplying a cooling fluid to electronics unit 304.

According to embodiments of the present disclosure, heat exchangers 306 can be positioned in a vertical arrangement with and/or above air transfer zone 308, electronics unit 304, and resistor grid 302, such that heat exchangers 306 are not blocked by structural components (e.g., panels, plates, sheets, enclosures, beams, and the like) of mining truck 100. In this configuration, ambient air that flows along a flow path 338 from an area in front of mining truck 100 can impact heat exchangers 306 without being significantly impeded by structural components of mining truck 100. Thus, heat exchangers 306 can be exposed to a direct (e.g., substantially unobstructed) flow of ambient air for cooling the cooling fluid flowing within heat exchangers 306. Such exposure may facilitate an efficient transfer of heat from the cooling fluid to the ambient air. In some embodiments, heat exchangers 306 may be mounted adjacent to one another, such that each can be exposed to a direct (e.g., substantially unobstructed) flow of ambient air. In some embodiments, heat exchangers 306 may include fans 330 configured to increase the flow of air through heat exchangers 306. In these embodiments, the fans can increase the rate of heat transfer from the cooling fluid to the ambient air by heat exchangers 306.

By the integrated configuration of thermal management system 300, resistor grid 302, and electronics unit 304 discussed above, thermal management system 300 can efficiently dissipate heat from resistor grid 302 and electronics unit 304 within a compact space on deck 310. Additionally, this configuration facilitates convenient access to resistor grid 302 and electronics unit 304 for procedures such as maintenance and/or repair. For example, both resistor grid 302 and electronics unit 304 can be conveniently accessed from deck 310, and resistor grid 302 may include one or more top-side access panels 360 for such procedures.

FIG. 4B shows a plan view of thermal management system 300 of FIG. 4A on first side 132 of the chassis 102 of mining truck 100 (FIG. 2). As shown, heated air flows toward front side 318 of resistor grid 302 in a first direction 348. Fins 342 of resistor grid 302 may direct the heated air into air transfer zone 308 and toward air transfer zone outlet 322, where it flows from air transfer zone 308 in a second direction 350 that is substantially perpendicular to first direction 348. The heated air flows from air transfer zone 308 to an area 352 adjacent first side 132 of chassis 102.

Except as described below, thermal management system 300 as illustrated in FIG. 5A includes the same components and details described in FIG. 4A, with like components associated with like reference numbers. FIG. 5A shows an embodiment of thermal management system 300 in which condenser tubes 332 are mounted in a vertical arrangement with and/or above resistor grid 302 and adjacent to heat exchangers 306. In this configuration, thermal management system 300 can occupy a reduced amount of space on deck 310.

FIG. 5B shows a plan view of the thermal management system 300 of FIG. 5A.

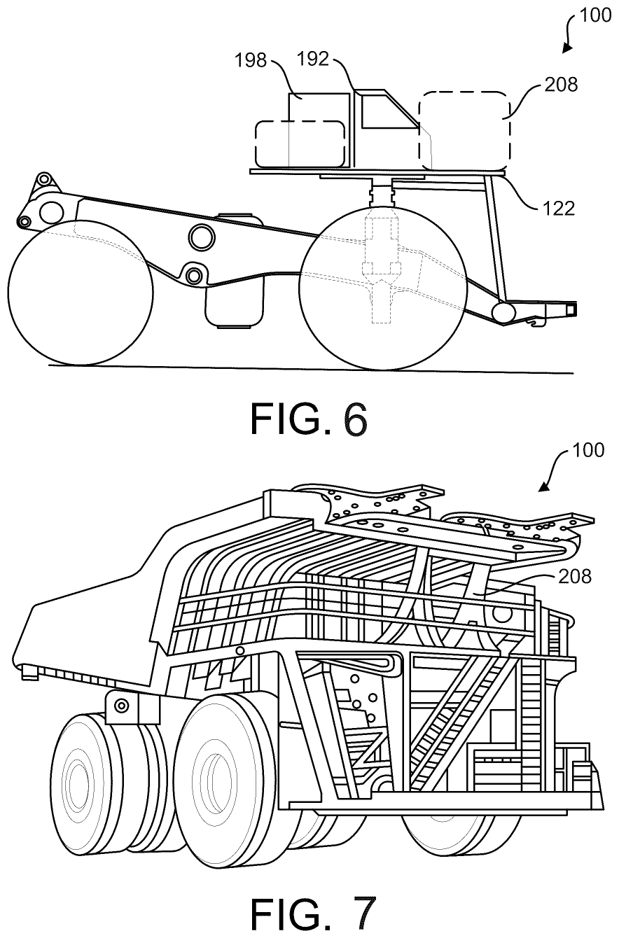

FIGS. 6-7 illustrate an embodiment of mining truck 100 including an on-board trolley system 208, such as a pantograph. As described above, a space forward of inverter cabinet 198 can be defined to receive or can already contain an on-board trolley system 208 for connecting to an overhead trolley during operation of mining truck 100. On-board trolley system 208, for example, can facilitate connection of mining truck 100 to an overhead trolley to assist mining truck 100 with traversal of uphill and/or difficult trails or roads and/or when mining truck 100 is carrying heavy loads.

Various modifications and additions can be made to the exemplary embodiments discussed without departing from the scope of the disclosed subject matter. For example, while the embodiments described above refer to particular features, the scope of this disclosure also includes embodiments having different combinations of features and embodiments that do not include all of the described features. Accordingly, the scope of the disclosed subject matter is intended to embrace all such alternatives, modifications, and variations that fall within the scope of the claims, together with all equivalents thereof.

Various aspects are described in this disclosure, which include, but are not limited to, the following aspects:

(1) A mining truck including: a chassis extending along a longitudinal length of the mining truck, the chassis having a front end portion and a rear end portion; a deck supported by the front end portion of the chassis; a resistor grid supported by the deck; an electronics unit supported by the deck and spaced apart from the resistor grid; and an air transfer zone arranged between the resistor grid and the electronics unit, the air transfer zone configured to receive exhaust air from the resistor grid.

(2) The mining truck of Aspect (1), wherein the electronics unit includes a battery.

(3) The mining truck of any one of Aspects (1)-(2), further including an insulation layer disposed between the air transfer zone and the electronics unit.

(4) The mining truck of any one of Aspects (1)-(3), wherein the resistor grid is configured to move the exhaust air in a first direction, and wherein the air transfer zone forms a flow path in a second direction that is substantially perpendicular to the first direction.

(5) The mining truck of Aspect (4), wherein the resistor grid includes one or more fins oriented to direct the exhaust air toward the second direction.

(6) The mining truck of any one of Aspects (4)-(5), wherein the air transfer zone is configured to vent the exhaust air in the second direction.

(7) The mining tuck of Aspect (6), wherein the deck has a first side and a second side opposite the first side, the second side including an operator cab of the mining truck and the first side including the air transfer zone, wherein the air transfer zone is configured to vent the exhaust air away from the mining truck from the first side, and wherein the second direction extends from the first side to an ambient area adjacent the first side.

(8) The mining truck of Aspect (7), further including: a mirror coupled to the first side of the mining truck; and a line-of-sight defined between the mirror and the operator cab; wherein neither of the resistor grid nor the electronics unit intersect the line-of-sight defined between the mirror and the operator cab.

(9) The mining truck of any one of Aspects (1)-(8), wherein the electronics unit includes one or more DC/DC converters.

(10) The mining truck of any one of Aspects (1)-(9), wherein the resistor grid includes a top-side access panel.

(11) The mining truck of any one of Aspects (1)-(10), further including one or more condenser tubes positioned above the resistor grid.

(12) The mining truck of any one of Aspects (1)-(11), further including a front support member positioned between the resistor grid and the air transfer zone, and wherein the front support member includes an upper portion and a lower portion, the upper portion removably attached to the lower portion.

(13) A mining truck including: a chassis extending along a longitudinal length of the mining truck, a deck supported by the chassis; a resistor grid supported by the deck; and one or more heat exchangers positioned above the resistor grid, the one or more heat exchangers configured to receive a cooling fluid for cooling one or more electronic components of the mining truck.

(14) The mining truck of Aspect (13), further including an electronics unit spaced apart from the resistor grid and an air transfer zone arranged between the resistor grid and the electronics unit.

(15) The mining truck of Aspect (14), wherein the one or more heat exchangers is positioned above the air transfer zone, such that the air transfer zone is enclosed by the resistor grid, the electronics unit, the deck, and a base support member of the one or more heat exchangers.

(16) The mining truck of any one of Aspects (14)-(15), further including an insultation layer disposed between the air transfer zone and the one or more heat exchangers.

(17) The mining truck of any one of Aspects (14)-(16), wherein the one or more heat exchangers is positioned above the electronics unit.

(18) The mining truck of Aspect (13), wherein the one or more electronics components of the mining truck includes a battery of the mining truck and an electronics unit positioned on the deck.

(19) The mining truck of Aspect (18), wherein the one or more heat exchangers includes a first heat exchanger configured to cool the battery of the mining truck and a second heat exchanger configured to cool the electronics unit.

(20) The mining truck of any one of Aspects (18-19), further including a radiator configured to cool the electronics unit, wherein the one or more heat exchangers is configured to cool the battery of the mining truck.

We claim:

1. A mining truck comprising:
a chassis extending along a longitudinal length of the mining truck, the chassis having a front end portion and a rear end portion;
a deck supported by the front end portion of the chassis;
a resistor grid supported by the deck;
an electronics unit supported by the deck and spaced apart from the resistor grid; and
an air transfer zone arranged between the resistor grid and the electronics unit, the air transfer zone configured to receive exhaust air from the resistor grid

2. The mining truck of claim 1, wherein the electronics unit includes a battery.

3. The mining truck of claim 1, further comprising an insulation layer disposed between the air transfer zone and the electronics unit.

4. The mining truck of claim 1, wherein the resistor grid is configured to move the exhaust air in a first direction, and
wherein the air transfer zone forms a flow path in a second direction that is substantially perpendicular to the first direction.

5. The mining truck of claim 4, wherein the resistor grid includes one or more fins oriented to direct the exhaust air toward the second direction.

6. The mining truck of claim 4, wherein the air transfer zone is configured to vent the exhaust air in the second direction.

7. The mining truck of claim 6, wherein the deck has a first side and a second side opposite the first side, the second side including an operator cab of the mining truck, the first side including the air transfer zone,
wherein the air transfer zone is configured to vent the exhaust air away from the mining truck from the first side, and
wherein the second direction extends from the first side to an ambient area adjacent the first side.

8. The mining truck of claim 7, further comprising:
a mirror coupled to the first side of the mining truck; and
a line-of-sight defined between the mirror and the operator cab;
wherein neither of the resistor grid nor the electronics unit intersect the line-of-sight defined between the mirror and the operator cab.

9. The mining truck of claim 1, wherein the electronics unit comprises one or more DC/DC converters.

10. The mining truck of claim 1, wherein the resistor grid comprises a top-side access panel.

11. The mining truck of claim 1, further comprising one or more condenser tubes positioned above the resistor grid.

12. The mining truck of claim 1, further comprising a front support member positioned between the resistor grid and the air transfer zone, and
wherein the front support member includes an upper portion and a lower portion, the upper portion removably attached to the lower portion.

13. A mining truck comprising:
a chassis extending along a longitudinal length of the mining truck;
a deck supported by the chassis;
a resistor grid supported by the deck; and
one or more heat exchangers positioned above the resistor grid, the one or more heat exchangers configured to receive a cooling fluid for cooling one or more electronic components of the mining truck.

14. The mining truck of claim 13, further comprising an electronics unit spaced apart from the resistor grid and an air transfer zone arranged between the resistor grid and the electronics unit.

15. The mining truck of claim 14, wherein the one or more heat exchangers is positioned above the air transfer zone, such that the air transfer zone is enclosed by the resistor grid, the electronics unit, the deck, and a base support member of the one or more heat exchangers.

16. The mining truck of claim 14, further comprising an insulation layer disposed between the air transfer zone and the one or more heat exchangers.

17. The mining truck of claim 14, wherein the one or more heat exchangers is positioned above the electronics unit.

18. The mining truck of claim 13, wherein the one or more electronic components of the mining truck includes a battery of the mining truck and an electronics unit positioned on the deck.

19. The mining truck of claim 18, wherein the one or more heat exchangers includes a first heat exchanger configured to cool the battery of the mining truck and a second heat exchanger configured to cool the electronics unit.

20. The mining truck of claim 18, further comprising a radiator configured to cool the electronics unit, wherein the one or more heat exchangers is configured to cool the battery of the mining truck.
